(19) United States
(12) Patent Application Publication
(10) Pub. No.: US 2010/0118081 A1
(43) Pub. Date: May 13, 2010

(54) Dead Volume Removal From An Extrusion Printhead

(75) Inventor: David K. Fork, Los Altos, CA (US)

Correspondence Address: BEVER, HOFFMAN & HARMS, LLP, 901 CAMPISI WAY, SUITE 370, CAMPBELL, CA, 95008, US

(73) Assignee: Palo Alto Research Center Incorporated, Palo Alto, CA (US)

(21) Appl. No.: 12/267,147

(22) Filed: Nov. 7, 2008

(51) Int. Cl. B41J 2/165

(52) U.S. Cl. 347/22; 137/13

(57) ABSTRACT

A micro-extrusion printhead assembly utilized in a micro-extrusion system to form parallel extruded lines on a substrate includes a material feed system for pushing/drawing materials through flow channels and out of extrusion nozzles defined in the printhead assembly. The micro-extrusion printhead includes a layered nozzle structure sandwiched between plate structures, and the flow channels are defined by slots and holes formed in the layered/plate structures. Prior to use, solid forming fluid is passed through the printhead assembly such that the forming fluid occupies dead volumes (e.g., corners and pockets) of the flow channels. The solid forming fluid is then flushed from the flow channels such that portions of the solid forming fluid are retained in the dead volumes. The retained portions are then solidified to form solid structures that fill the dead volumes. In subsequent use, the solid structures prevent stagnation of extrusion material in the dead volumes.

### FIELD OF THE INVENTION

The present invention is related to fluid conduit devices, and more particularly to extrusion printheads for micro-extrusion systems.

### BACKGROUND

In order to meet the demand for low cost large-area semiconductors, micro-extrusion methods have been developed that include extruding a paste including a dopant bearing material (dopant ink) along with a sacrificial material (non-doping ink) onto the surface of a semiconductor substrate, and then heating the semiconductor substrate such that a dopant (e.g., phosphorous or boron) disposed in the dopant ink diffuses into the substrate to form the desired doped region or regions. The co-extrusion process utilizes a co-extrusion printhead having to inlet ports for receiving the paste (i.e., dopant ink and non-doping ink), multiple outlet orifices (nozzle openings) that are arranged to co-extrude the paste in the desired manner, and a combination of plenums and flow channels defined in the extrusion printhead that channel the paste between the inlet ports and the nozzle openings.

In comparison to screen printing techniques, the co-extrusion of dopant and sacrificial materials on the substrate provides superior control of the feature resolution of the doped regions, and facilitates deposition without contacting the substrate, thereby avoiding wafer breakage. Such fabrication techniques are disclosed, for example, in U.S. Patent Application No. 20080138456, which is incorporated herein by reference in its entirety.

A problem with the co-extrusion process described above, and in general with fluid conduit devices (e.g., valves) used for similar or related purposes, is that paste-like materials can stagnate in corners and pockets (dead volumes) of the fluid conduit device (e.g., the printhead described above), making this stagnant material difficult to clean out. More importantly, if the stagnant material sits long enough, it can agglomerate into clog forming material. That is, if the co-extrusion printhead is used and then stored, the stagnant material can dry out, harden, and then form a sizable chunk of clog forming material trapped inside the printhead, thereby increasing manufacturing costs by requiring replacement of clogged printheads and discarding of flawed workpieces. Clogging is one of the most significant risks of extrusion printing technology relative to alternate methods such as screen printing.

What is needed is a method for modifying a micro-extrusion printhead (or other similar fluid conduit device) that avoids the clogging problem associated with conventional printheads. What is also needed is a printhead (or other similar fluid conduit device) modified by the novel method.

### SUMMARY OF THE INVENTION

The present invention is directed to a novel method that, prior to use in “normal” operation, purposefully traps a hardenable material in the dead volume spaces of flow channels defined through a micro-extrusion printhead (or other fluid conduit device) while leaving the main channel regions open to conduct extrusion material, thereby avoiding the clogging problem associated with conventional printheads by reducing or eliminating regions where the extrusion materials can stagnate and dry out to form clogs.

In accordance with an embodiment of the present invention, a method for producing a fluid conduit device (e.g., a micro-extrusion printhead assembly) begins by fabricating a body defining an inlet port, an outlet orifice, and a flow channel communicating between the inlet port and the outlet orifice through the body. The body of the fluid conduit device is fabricated using one or more solid (first) materials, such as a metal or hard plastic, that remain in a solid form during subsequent processing and extrusion process. The present invention is particularly directed to fluid conduit devices in which the body is constructed such that the flow channel includes one or more direction changes (corners) that form dead volume spaces (i.e., regions of the flow channel in which extrusion material remains relatively stagnant during subsequent extrusion processes). In order to prevent stagnant extrusion material from forming clogs, the manufacturing process further includes minimizing/eliminating the dead volume spaces in the flow channel by filling the dead volume spaces with a hardenable (second) material that can be inserted into the flow channel in a liquid form, and then cured or otherwise hardened into a solid form. In accordance with an embodiment of the present invention, during a first phase of dead volume minimization, the hardenable material is introduced as a solid forming fluid (e.g., a liquid, paste, or gel) that fills the entire flow channel space (i.e., the main flow channel regions and the dead volume spaces) as it flows through the micro-extrusion printhead. During a second phase, while the hardenable material is still in the fluid form, a second (non-hardening) fluid is introduced into the printhead in a way that displaces the hardenable material from the main flow channels, but does not displace the hardenable material remaining in the dead volume spaces. In one embodiment the solid forming fluid and the displacement fluid are immiscible. The hardenable material disposed in the dead volume spaces is then solidified and the second fluid is removed from the main flow channels. The resulting micro-extrusion printhead includes the original solid materials (e.g., metal) that define the flow channels, and the solid hardenable material disposed in the dead volumes spaces of the flow channels in a way that does not impede the subsequent passage of a extrusion material (e.g., paste) through the main flow channel regions during “normal” extrusion printing.

According to an aspect of the present invention, the hardenable material is hardened (solidified) either while the second (displacing) fluid is still in the flow channel, or after the second fluid is removed from the flow channel. In accordance with one specific embodiment, the hardening process involves a chemical reaction between the hardenable (first) fluid and the displacing (second) fluid, such as the hardening of a two component epoxy. In accordance with another specific embodiment, the hardening process involves utilizing a thermoset material and elevating the temperature of the printhead. In yet another specific embodiment the hardening process includes, after the second phase is completed, subjecting the printhead to ionizing radiation that penetrates the printhead and activates a solidifying reaction in the hardenable material.

In a preferred embodiment, the hardenable material undergoes limited volume change during the hardening process. This goal can be achieved, for example, by using a hardenable material with a significant volume fraction (>20%) of solid particles.

In accordance with a specific embodiment, the present invention is utilized to modify a micro-extrusion printhead assembly utilized in a micro-extrusion system that forms parallel extruded lines of functional material on a substrate surface. According to an aspect of the present invention, the micro-extrusion printhead includes a layered nozzle structure sandwiched between a first (back) plate structure and a second (front) plate structure. The layered nozzle structure is made up of stacked metal (or other rigid material) plates including a top nozzle plate, an optional bottom nozzle plate, and a nozzle outlet plate sandwiched between the top and bottom nozzle plates (or between the top nozzle plate and the second plate structure). The various plates and structures of the printhead are etched or otherwise formed to define openings that, when the plates are operably assembled to form the layered nozzle structure, combine to define flow channels extending between inlet ports formed on back plate structure and outlet orifices (nozzles) formed by layered nozzle structure. In a specific embodiment, each nozzle is formed by an elongated nozzle channel that is etched or otherwise formed in the nozzle outlet plate, and portions of the top and bottom nozzle plates that serve as upper and lower walls of the extrusion nozzle. According to the present invention, dead volume spaces (e.g., corner regions inside the flow channel and disposed at interfaces between adjacent plates) are filled with the solid forming fluid, and then processed as described above to form hardenable material that prevents the stagnation of.

According to another embodiment of the present invention, the associated micro-extrusion system includes a co-extrusion printhead assembly that is constructed to co-extrude two different materials in order to form closely spaced high-aspect ratio gridline structures on a substrate surface or narrow printed lines of dopant bearing paste, wherein the co-extrusion printhead assembly is modified to include the clog-preventing structures in the manner described above. Similar to the single material extrusion embodiments described above, the co-extrusion printhead assembly includes upper an lower plate structures that serve to guide the two extrusion materials via separate conduits from corresponding inlet ports to a layered nozzle structure, and a layered nozzle structure that is formed in accordance with the various specific embodiments described above to bias the extruded bead toward the target substrate. However, in the co-extrusion embodiment, the extruded bead includes a sacrificial material and a gridline (functional) material arranged such that the gridline material forms a high-aspect ratio gridline structure that is supported between two sacrificial material portions (the sacrificial portions are subsequently removed). The formation of such co-extruded bead structures requires the compression of the gridline material between the two sacrificial material portions, which is achieved by utilizing a three-part nozzle channel including a central channel and two side channels that converge with the central channel at a merge point located adjacent to the nozzle orifice (opening). The gridline material is transferred through the central nozzle channel by way of a first flow channel, and the sacrificial material is transferred through the two side nozzle channels by way of second and third flow channels such that the gridline material is compressed between the two sacrificial material portions at the merge point, and is forced through the nozzle orifice (opening) to form a high-aspect ratio gridline structure (bead) that is supported between the two sacrificial material portions. As with the single material extrusion printhead, the co-extrusion printhead is fabricated to include clog preventing portions located in dead volumes of the first flow channel feeding the central nozzle channel, and the second and third flow channels feeding the side nozzle channels.

### BRIEF DESCRIPTION OF THE DRAWINGS

These and other features, aspects and advantages of the present invention will become better understood with regard to the following description, appended claims, and accompanying drawings, where:

FIG. 1 is a side view showing a portion of a micro-extrusion system including a micro-extrusion printhead assembly formed in accordance with an embodiment of the present invention;

FIG. 2 is a side view showing the micro-extrusion system of FIG. 1 in additional detail;

FIG. 3 is an exploded cross-sectional side view showing a generalized micro-extrusion printhead assembly utilized in the system of FIG. 1;

FIGS. 4(A) and 4(B) are cross-sectional side views showing a portion of a micro-extrusion printhead assembly during normal operation;

FIGS. 5(A) and 5(B) are cross-sectional side views depicting the formation of a clog by stagnant extrusion material in the printhead assembly portion of FIG. 4(B);

FIGS. 6(A), 6(B) and 6(C) are simplified cross-sectional side view showing portions of a micro-extrusion printhead assembly during the formation of clog-preventing structures according to an embodiment of the present invention;

FIG. 7 is a simplified cross-sectional side view showing the printhead assembly portion of FIG. 6(C) during a subsequent extrusion process;

FIG. 8 is a front view showing a micro-extrusion system including a generalized co-extrusion printhead assembly according to another embodiment of the present invention;

FIG. 9 is an exploded perspective view showing the co-extrusion printhead assembly of FIG. 8 in additional detail;

FIG. 10 is an exploded partial perspective view showing a portion of the printhead assembly of FIG. 9 in additional detail;

FIG. 11 is a simplified exploded partial perspective view showing a portion of a generalized layered nozzle structure utilized in the co-extrusion printhead assembly of FIG. 8; and

FIG. 12 is a cross-sectional side view showing an exemplary co-extruded gridline structure generated on a substrate surface by the co-extrusion printhead assembly of FIG. 8.

### DETAILED DESCRIPTION

The present invention is described below with specific references to an improvement in micro-extrusion systems, but is applicable to any similar fluid conduit device. The following description is presented to enable one of ordinary skill in the art to make and use the invention as provided in the context of a particular application and its requirements. As used herein, directional terms such as “upper”, “top”, “lower”, “bottom”, “front”, “rear”, and “lateral” are intended to provide relative positions for purposes of description, and are not intended to designate an absolute frame of reference. In addition, the phrases “integrally connected” and “integrally molded” is used herein to describe the connective relationship between two portions of a single molded or machined structure, and are distinguished from the terms “connected” or “coupled” (without the modifier “integrally”), which indicates two separate structures that are joined by way of, for example, adhesive, fastener, clip, or movable joint. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

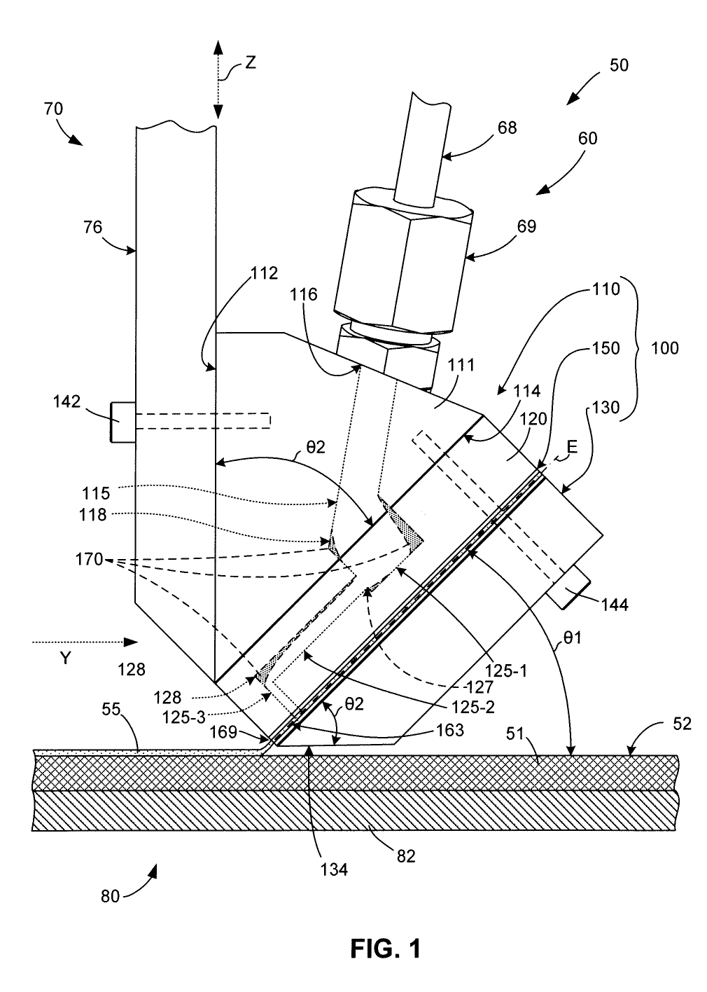

FIG. 1 is a simplified side view showing a portion of a micro-extrusion system 50 for forming parallel extruded material lines 55 on upper surface 52 of a substrate 51. Micro-extrusion system 50 includes an extrusion printhead assembly (fluid conduit device) 100 that is operably coupled to a material feed system 60 by way of at least one feedpipe 68 and an associated fastener 69.

The materials are supplied in a paste through pushing and/or drawing techniques (e.g., hot and cold) in which the materials are pushed (e.g., squeezed, etc.) and/or drawn (e.g., via a vacuum, etc.) through flow channels 115 and 125-x formed in extrusion printhead assembly 100, and out one or more outlet orifices (exit ports, or nozzle outlets) 169 that are respectively defined in a lower portion of printhead assembly 100. Micro-extrusion system 50 also includes a X-Y-Z-axis positioning mechanism 70 including a mounting plate 76 for rigidly supporting and positioning printhead assembly 100 relative to substrate 51, and a base 80 including a platform 82 for supporting substrate 51 in a stationary position as printhead assembly 100 is moved in a predetermined (e.g., Y-axis) direction over substrate 51. In alternative embodiment (not shown), printhead assembly 100 is stationary and base 80 includes an X-Y axis positioning mechanism for moving substrate 51 under printhead assembly 100.

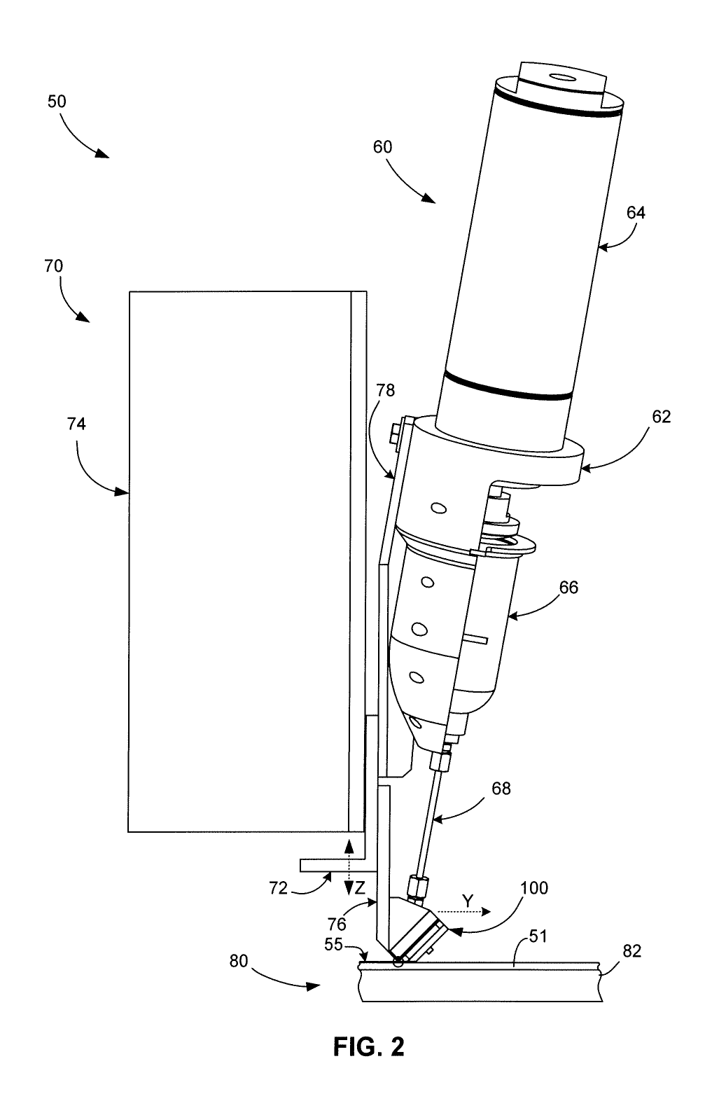

FIG. 2 shows material feed system 60, X-Y-Z-axis positioning mechanism 70 and base 80 of micro-extrusion system 50 in additional detail. The assembly shown in FIG. 2 represents an experimental arrangement utilized to produce solar cells on a small scale, and those skilled in the art will recognize that other arrangements would typically be used to produce solar cells on a larger scale. Referring to the upper right portion of FIG. 2, material feed system 60 includes a housing 62 that supports a pneumatic cylinder 64, which is operably coupled to a cartridge 66 such that material is forced from cartridge 66 through feedpipe 68 into printhead assembly 100. Referring to the left side of FIG. 2, X-Y-Z-axis positioning mechanism 70 includes a Z-axis stage 72 that is movable in the Z-axis (vertical) direction relative to target substrate 51 by way of a housing/actuator 74 using known techniques. Mounting plate 76 is rigidly connected to a lower end of Z-axis stage 72 and supports printhead assembly 100, and a mounting frame 78 is rigidly connected to and extends upward from Z-axis stage 72 and supports pneumatic cylinder 64 and cartridge 66. Referring to the lower portion of FIG. 2, base 80 includes supporting platform 82, which supports target substrate 51 as an X-Y mechanism moves printhead assembly 100 in the X-axis and Y-axis directions (as well as a couple of rotational axes) over the upper surface of substrate 51 utilizing known techniques.

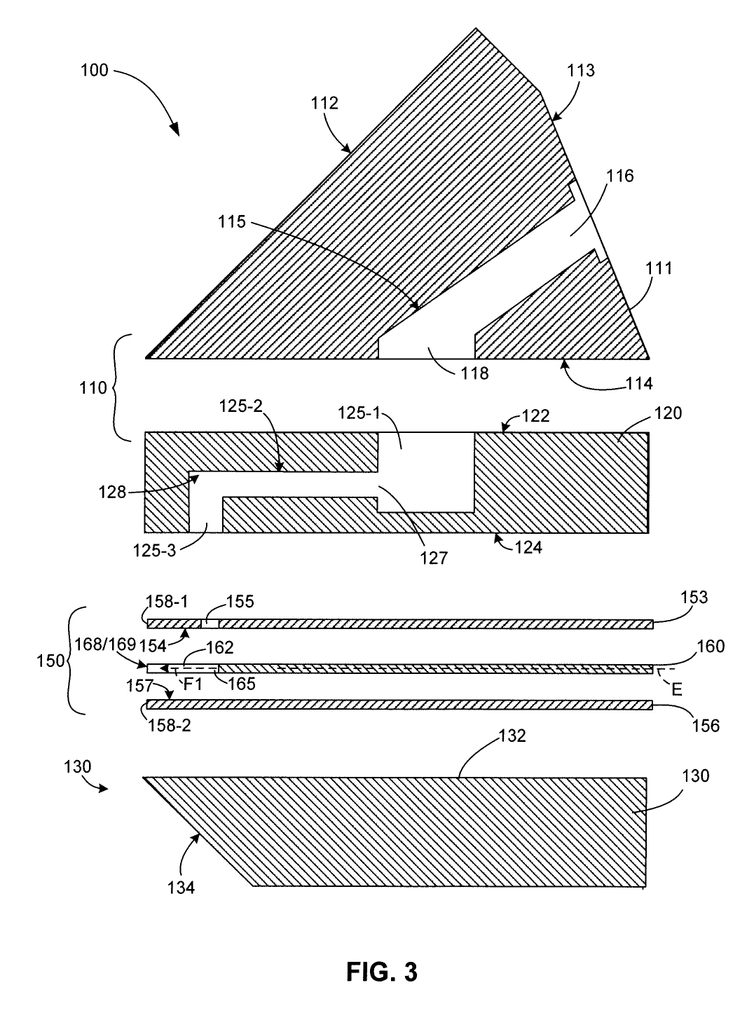

As shown in FIG. 1 and in exploded form in FIG. 3, layered micro-extrusion printhead assembly 100 includes a first (back) plate structure 110, a second (front) plate structure 130, and a layered nozzle structure 150 connected therebetween. As described in additional detail below, back plate structure 110 and front plate structure 130 are solid (e.g., metal) structures, and at least one of back plate structure 110 and front plate structure 130 defines one or more hollow regions that form one or more flow channels to conduct the extrusion material from an inlet port 116 to layered nozzle structure 150. Back plate structure 110 and front plate structure 130 also serve to rigidly support layered nozzle structure 150 such that extrusion nozzles 163 defined in layered nozzle structure 150 are pointed toward substrate 51 at a predetermined tilted angle θ1 (e.g., 45° ), whereby extruded material traveling down each extrusion nozzle 163 toward its corresponding nozzle orifice 169 is directed toward target substrate 51.

Each of back plate structure 110 and front plate structure 130 includes one or more integrally molded or machined metal (or other rigid material) parts. In the disclosed embodiment, back plate structure 110 includes an angled back plate 111 and a back plenum 120, and front plate structure 130 includes a single-piece metal plate. Angled back plate 111 includes a front surface 112, a side surface 113, and a back surface 114, with front surface 112 and back surface 114 forming a predetermined angle θ2 (e.g., 45°; shown in FIG. 1). Angled back plate 111 also defines a (first) flow channel portion 115 that extends from a threaded countersunk inlet port 116 defined in side wall 113 to a (first) elbow (i.e., a bend) 118 located adjacent to a bore outlet defined in back surface 114. Back plenum 120 defines a (second) flow channel portion 125-1 that is aligned to communicate with the bore outlet located adjacent to elbow 118, a (third) flow channel portion 125-2 that communicates with flow channel portion 125-1 by way of a neck region 127, and a (fourth) flow channel region 125-3 that communicates with flow channel 125-2 by way of a (second) elbow 128, and an outlet that feeds into extrusion nozzles 163 in the manner described below. As illustrated, flow channel portions 115, 125-1, 125-2 and 125-3 cooperates to feed extrusion material from inlet port 116 to layered nozzle structure 150 during an extrusion process.

Referring in to the lower portion of FIG. 1, front plate structure 130 includes a front surface 132 and a beveled lower surface 134 that form predetermined angle θ2 (shown in FIG. 1).

Layered nozzle structure 150 is disposed between back plate structure 110 and front plate structure 130, and includes two or more stacked plates (e.g., a metal such as aluminum, steel or plastic) that combine to form one or more extrusion nozzles 163. In the simplified embodiment shown in FIG. 3, layered nozzle structure 150 includes a top nozzle plate 153, a bottom nozzle plate 156, and a nozzle outlet plate 160 sandwiched between top nozzle plate 153 and bottom nozzle plate 156. Top nozzle plate 153 defines an inlet port (through hole) 155, and has a (first) front edge 158-1. Bottom nozzle plate 156 is a substantially solid (i.e., continuous) plate having a (third) front edge 158-2. Nozzle outlet plate 160 includes a (second) front edge 168 and defines an elongated nozzle channel 162 extending in a predetermined first flow direction F1 from a closed end 165 to an nozzle orifice 169 defined through front edge 168. When operably assembled (e.g., as shown in FIG. 1), nozzle outlet plate 160 is sandwiched between top nozzle plate 153 and bottom nozzle plate 156 such that elongated nozzle channel 162, a front portion 154 of top nozzle plate 153, and a front portion 157 of bottom nozzle plate 156 combine to define elongated extrusion nozzle 163 that extends from closed end 165 to nozzle orifice 169. In addition, top nozzle plate 153 is mounted on nozzle outlet plate 160 such that inlet port 155 is aligned with closed end 165 of elongated channel 162, whereby extrusion material forced through inlet port 155 flows in direction F1 along extrusion nozzle 163, and exits from layered nozzle structure 150 by way of nozzle orifice 169 to form bead 55 on substrate 51.

Referring again to FIG. 1, when operably assembled and mounted onto micro-extrusion system 50, angled back plate 111 of printhead assembly 100 is rigidly connected to mounting plate 76 by way of one or more fasteners (e.g., machine screws) 142 such that beveled surface 134 of front plate structure 130 is positioned close to parallel to upper surface 52 of target substrate 51. One or more second fasteners 144 are utilized to connect front plate structure 130 to back plate structure 110 with layered nozzle structure 150 pressed between the back surface of front plate structure 130 and the back surface of back plenum 120. In addition, material feed system 60 is operably coupled to flow channel 115 by way of feedpipe 68 and fastener 69 using known techniques, and extrusion material forced into flow channel 115 is redirected by elbow 118 to layered nozzle structure 150 by way of flow channel portion 125-1, neck 127, flow channel portion 125-2, elbow 128, and flow channel 125-3. The extrusion material exiting flow channel portion 125-3 enters the closed end of nozzle 163 by way of a third elbow formed at inlet 155 by closed end 165 (both shown in FIG. 3), and flows in direction F1 down nozzle 163 toward outlet 169. Referring to FIG. 3, the extrusion material flowing in the nozzle (i.e., traveling in direction F1 along channel 162) flows in (or parallel to) a lateral extrusion plane E defined by the nozzle outlet plate 160, and is directed through the outlet orifice (printhead nozzle) 169. Referring back to FIG. 1, because the extruded material is guided along the extrusion plane E at the tilted angle θ2 as it exits nozzle orifice 169, layered micro-extrusion printhead 100 reliably directs the extruded material toward substrate 51 in a manner that facilitates high volume solar cell production.

According to the present invention, as shown in FIG. 1, clog-preventing structures 170 are formed in dead volume spaces communicating with flow channels 115 and 125-1 to 125-3 of printhead assembly 100 in order to prevent extrusion material from stagnating in these regions and forming clogs. In particular, the body formed by front plate structure 110, back plate structure 130 and layered nozzle structure 150 is composed substantially of one or more solid (first) materials (e.g., stainless steel), and clog-preventing structures 170 composed of a hardenable (second) material are permanently attached to the inside wall of the body in elbow regions 118 and 128, and in neck region 127 at locations (i.e., dead volume spaces) where flow of extrusion material could otherwise stagnate and harden. The hardenable (second material) may be for example wax, thermoplastic, thermoset plastic, epoxy of various types including two-component acrylic or urethane epoxy. An example epoxy that may be used is Loctite Hysol™ E-60HP epoxy adhesive which has a 60 minute work life and high peel and high shear strength. By forming clog-preventing structures 170 in these dead volume spaces using the novel method described below, printhead assembly 100 reliably extrudes material during the production of solar cells without interruption due to clogs, thereby reducing manufacturing costs.

For optimal flow properties during the displacement of the hardenable material by the non-hardenable material, the latter should have similar Theological properties, notably the viscosity at the shear levels induced during displacement. For example, a suitable displacement fluid can be prepared by dissolving a viscosifier such as cellulose ether, for example Methocel K100M available from the Dow Chemical Corporation, in distilled water.

According to a preferred embodiment at least one of the nozzle structure materials, the output geometry, and the internal conduit geometry of printhead assembly 100 are modified to cause the extrusion material (bead) traveling through extrusion nozzle 163 (i.e., in or parallel to the lateral extrusion plane E) to be reliably directed (angled) toward the target substrate as it leaves the printhead nozzle orifice. Printhead assembly 100 that include the desired modifications are described in additional detail in co-owned and co-pending U.S. patent application Ser. No. ______ entitled “DIRECTIONAL EXTRUDED BEAD CONTROL”, filed with the present application, which is incorporated herein by reference in its entirety. In an alternative embodiment, a structure is provided to direct airflow against the extruded bead to achieve the desired bias against the substrate, as set forth in co-owned and co-pending U.S. patent application Ser. No. ______ entitled “MICRO-EXTRUSION SYSTEM WITH BEAD DEFLECTING MECHANISM”, filed with the present application, which is incorporated herein by reference in its entirety.

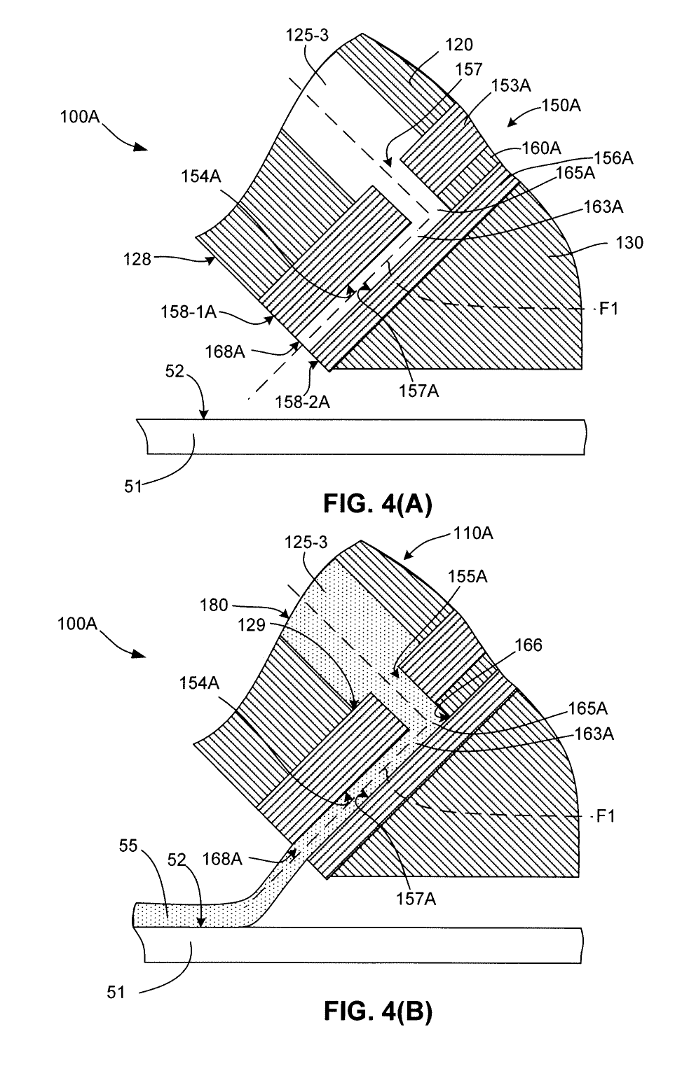

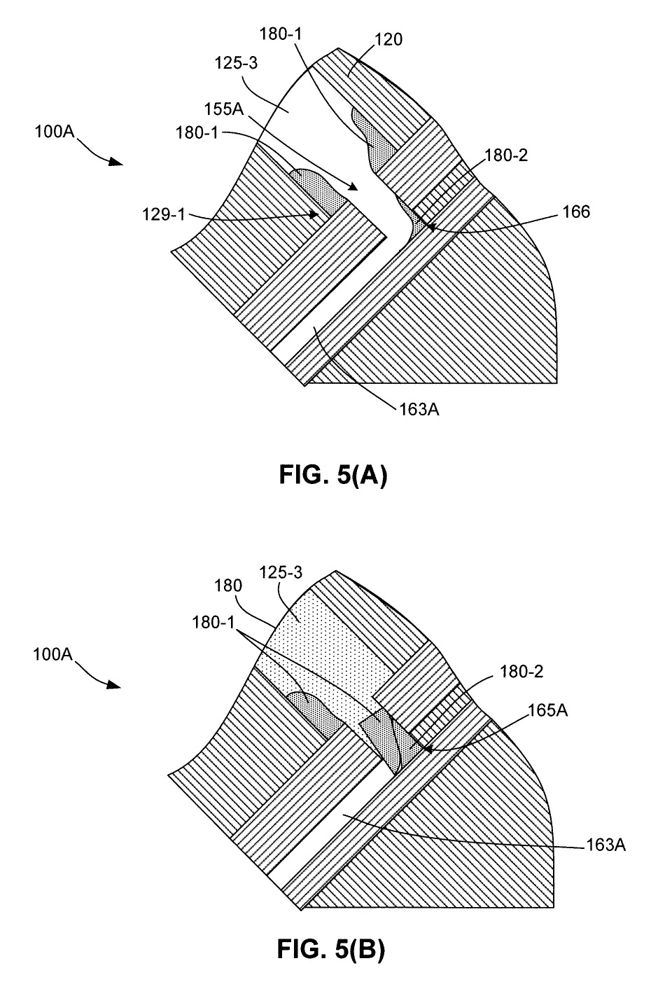

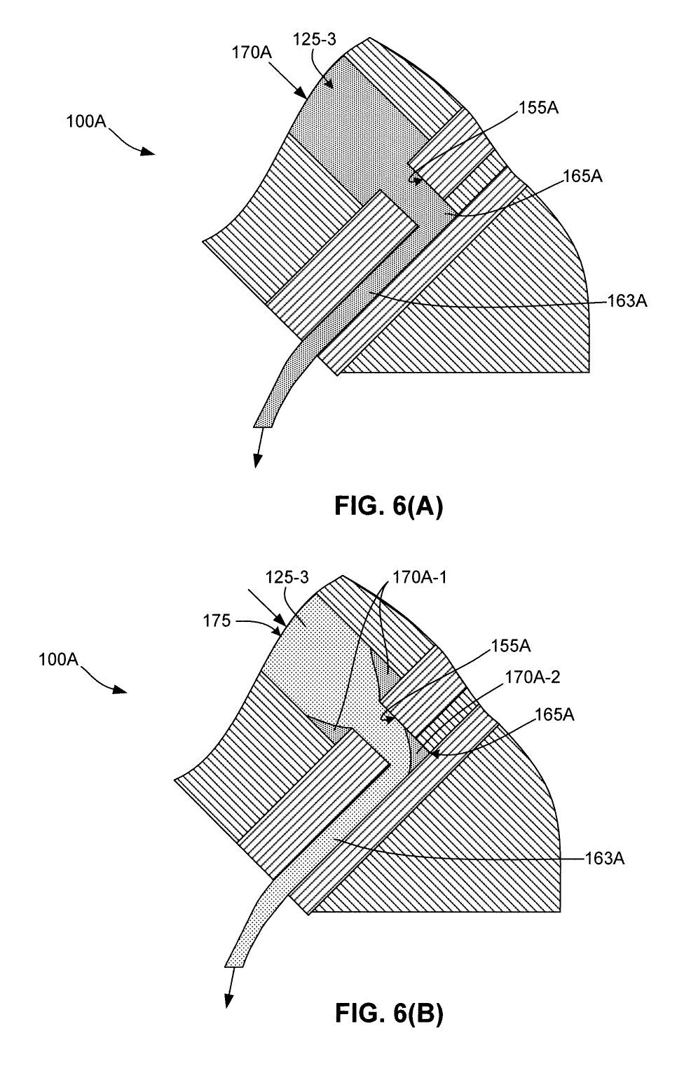

FIGS. 4(A) to 5(B) describe the clogging problem addressed by the present invention, and FIGS. 6(A) to 6(C) describe the novel method for preventing the clogging problem with reference to a micro-extrusion printhead assembly similar to that utilized in the described above with reference to FIGS. 1-3. Each of these figures illustrates a portion of a printhead assembly 100A including an interface between a top plate structure 110A and a layered nozzle structure 150A that are essentially identical to those described above. For example, FIG. 4(A) shows a partial cross-sectional view of printhead assembly portion 100A prior to the formation of clog-preventing structures according to the present invention, where printhead assembly portion 100A includes a layered nozzle structure 150A sandwiched between a back plenum 120 and a front plate structure 130A, which are similar to those described above with reference to FIG. 3. Back plenum 120 defines a flow channel portion 125-3 that communicates with an elbow (closed end) 165A of a nozzle 163A by way of a neck region 155A defined at the interface between back plenum 120 and top nozzle plate 153A. In combination with side walls formed by nozzle outlet plate 160A (not shown), portion 154A of top nozzle plate 153A and portion 157A of bottom nozzle plate 156A form the upper and lower walls, respectively, of nozzle 163A, whereby extrusion material entering nozzle 163A from conduit 125 generally flows along the dashed line F1 to outlet orifice 169A. Note that front edge 168A of nozzle outlet plate 160A, front edge 158-1A of top nozzle plate 153A, and front edge 158-2A of bottom nozzle plate 156A are coplanar with front edge 128 of back plenum 120, forming a front edge of printhead assembly 100A. In one exemplary embodiment, a thickness of top nozzle plate 153A is 300 microns, bottom nozzle plate 156A is 25 microns thick, nozzle outlet plate 160A is 50 microns thick, a width of nozzle orifice 169A is 200 microns, and a length of nozzle 163A is 2000 microns.

FIG. 4(B) is a simplified cross-sectional side view showing the portion of FIG. 4(A) during operation of printhead assembly 100A. Referring to FIG. 4(B), extrusion material 180 inserted into printhead assembly 100A by way of an inlet port (e.g., see inlet port 116 of FIG. 1) is forced from flow channel portion 125-3 through neck region 155A to elbow 165A of nozzle 163A, where it turns and passes between upper/lower wall portions 154A and 157A to outlet orifice 168A, at which point the extrusion material is extruded onto upper surface 52 of substrate 51 in the form of a bead 55. In particular, extrusion material passing through top plate structure 110A is eventually conducted to flow channel portion 125-3, at which point the extrusion material encounters resistance due to the narrowing of the flow channel at neck region 155A. Those skilled in the art will recognize that portions of extrusion material located adjacent the center of the flow channel (e.g., adjacent to dashed line arrow F1) tends to be pushed by fluid pressure through neck 155A and into nozzle 163A, while portions of extrusion material located near the wall surface outside neck region 155A (e.g., annular corner region 129 at the interface between back plenum 120 and top nozzle plate 153A, and angled corner region 166 formed at the inter face of nozzle outlet plate 160A and bottom nozzle plate 156A) tends to stagnate. As a result, as shown in FIG. 5(A), stagnant extrusion material portions 180-1 and 180-2 remain in corner regions 129 and 166 after the extrusion process is completed, and often remains even after a rinsing fluid is passed through flow channel portion 125-3 and nozzle 163A (i.e., through neck 155A and elbow 165A). During periods between uses, extrusion material portions 180-1 and 180-2 dry out and form solid pieces. As illustrated in FIG. 5(B), extrusion material portions 180-1 and 180-2 may become displaced and/or combine to lodge in neck 155A or elbow 165A, forming a clog (blockage) that reduces or prevents the flow of extrusion material 180 between flow channel portion 125-3 and nozzle 163A during a subsequent extrusion operation, leading to the problems described above.

FIGS. 6(A) to 6(C) are cross-sectional side views showing a method for modifying printhead assembly 100A according to an embodiment of the present invention. First, as indicated in FIG. 6(A), a solid forming (first) fluid 170A is caused to flow through the flow channel of printhead assembly 100A (e.g., such that fluid 170A fills flow channel portion 125-3 and nozzle 163A, including all dead volume spaces located adjacent to neck 155A and elbow 165A). As described above, this process involves feeding the solid forming fluid into an inlet port (e.g., inlet port 116; see FIG. 1) of printhead assembly 100A. In one embodiment, solid forming fluid 170A includes a hardenable material (i.e., fluid 170A forms a solid structure when subject to a curing or other hardening process). Next, as indicated in FIG. 6(B), a second (displacing) fluid 175 is caused to pass between the inlet port and the exit port (i.e., through flow channel portion 125-3 and nozzle 163A) such that the solid forming fluid is displaced from the flow channel by the displacing liquid except for portions 170A-1 and 170A-2 of the solid forming fluid remaining in corner regions 129 and 165A of the flow channel. In accordance with a preferred embodiment, displacing fluid 175 and hardenable fluid 170A are immiscible. Finally, as indicated in FIG. 6(C), the remaining portions of the solid forming fluid in the dead volume regions are solidified utilizing a selected hardening process (indicated by wavy arrow H) to form clog preventing structures 170-1 and 170-2 that are permanently attached to the inside walls of the flow channel. In one embodiment the solidifying process is performed while the displacing fluid is still inside the flow channel for example by using a two component epoxy that cures in the presence of the displacing fluid with a cure time longer than the time needed to displace the epoxy. In another example the solid forming material is a thermoplastic that is displaced at a temperature above its melt point and then cooled. Exemplary thermoplastics include acrylic, polyacetal, polyethylene terephthalate, polycarbonate, polyetheretherketone, polypropylene, polystyrene and polyvinyl chloride. In another embodiment, the solidifying process is performed after the displacing fluid is drained from the flow channel. In one embodiment, the solid forming fluid includes a thermoset material (e.g., epoxy or polyimide), and the solidifying process is performed by elevating the temperature of the printhead assembly. In another alternative embodiment, the solidifying process is performed by subjecting the printhead to ionizing radiation that activates a solidifying reaction in the hardenable material (e.g., diglycidyl ether of bisphenol F epoxy resin) disposed in the solid forming fluid.

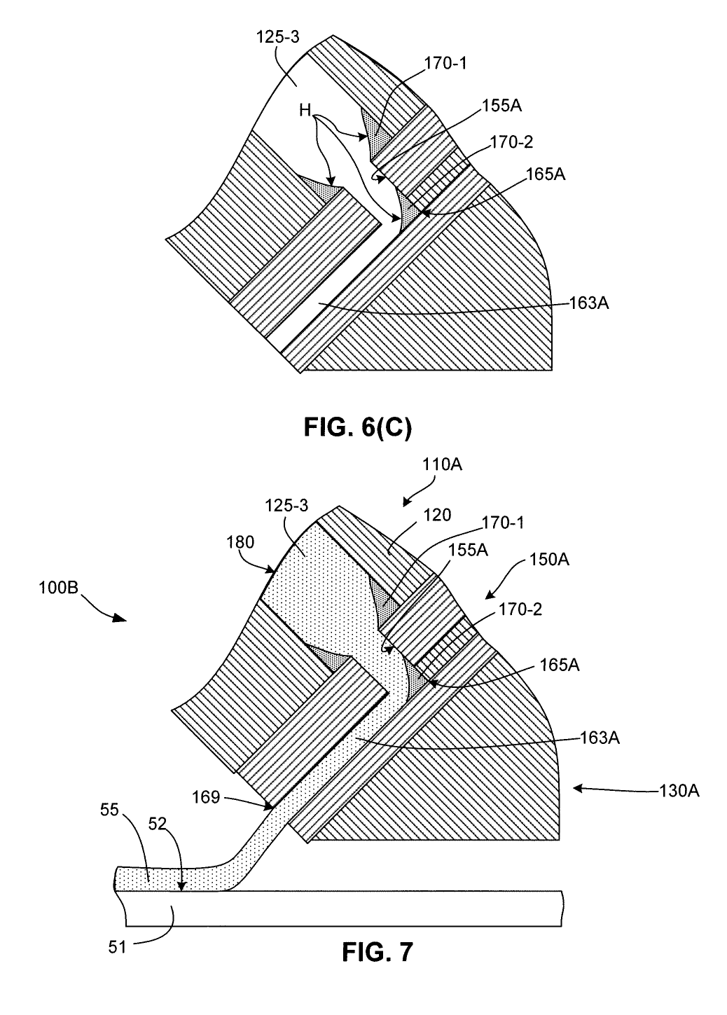

FIG. 7 shows a printhead assembly portion 100B after the solidifying process of the present invention is completed to form a printhead assembly portion 100B, and an extrusion material 180 is passed through printhead assembly portion 100B in the manner described above to form beads 55 on upper surface 52 of a target substrate 51. Top plate structure 110A (including plenum 120), bottom plate structure 130A, and layered nozzle structure 150A of printhead assembly portion 100B form a body composed substantially of a first material (e.g., stainless steel) that defines a hollow flow channel (i.e., including flow channel portion 125-3 and nozzle 163A) that communicates between an inlet (not shown) and outlet orifices (e.g., nozzle outlet orifice 169). According to the present invention, printhead assembly portion 100B includes a first clog-preventing structure 170-1 composed of a hardenable material (e.g., epoxy) that is permanently attached to the printhead material in neck region 129, and a second clog-preventing structure 170-2 composed of the hardenable material that is permanently attached to the printhead material in elbow region 165A. With clog-preventing structure 170-1 and 170-2 thus disposed, substantially all of extrusion material 180 is easily removed from the flow channel at the end of the extrusion process, thereby preventing the clogging problem described above.

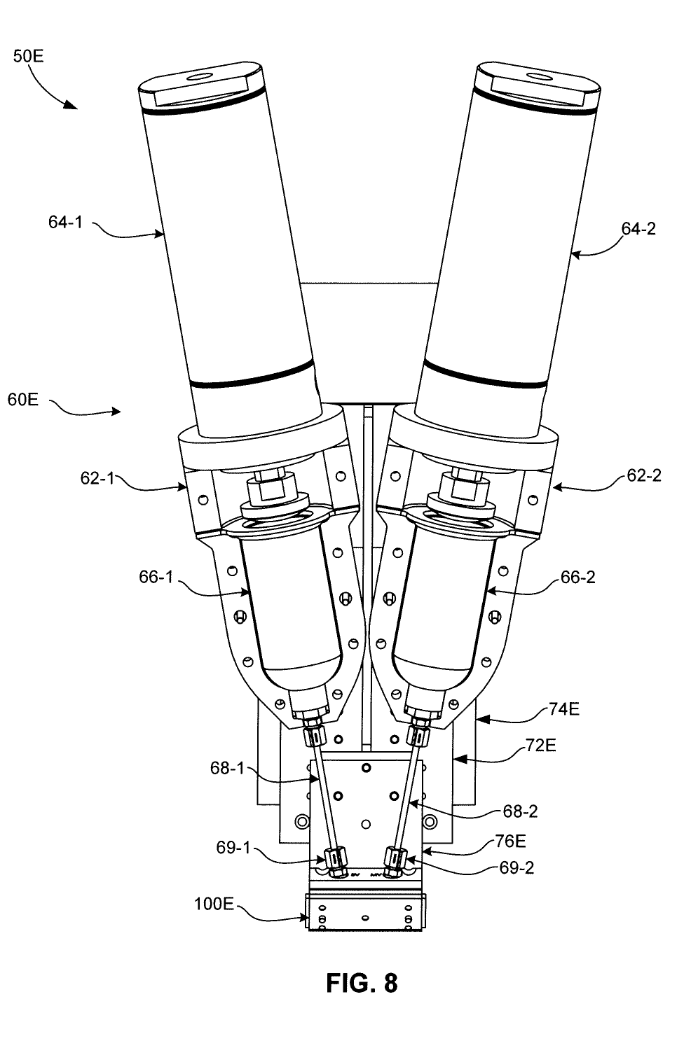

FIGS. 8-12 illustrate a co-extrusion system 50E according to another embodiment of the present invention. Co-extrusion system 50E includes a Z-axis positioning mechanism and X-Y axis positioning mechanism that are constructed and function in a manner similar to that described above with reference to FIGS. 1 and 2. As set forth in the following paragraphs, co-extrusion system 50E differs from the above-described embodiments in that it includes material feed system 60E having means for supplying two extrusion materials to a printhead assembly 100E, and printhead assembly 100E includes means for co-extruding the two extrusion materials in a manner that generates parallel high-aspect ratio gridline structures (described below with reference to FIG. 12). As set forth in the description below, co-extrusion printheads are multi-layered devices typically including eleven or more layers of individually machined material that is stack bonded to form the completed printhead assembly. Although the channels within one layer can often be designed to have a swept structure to minimize dead volume, other dead volume is unavoidable, particularly at the coupling between channels in adjacent layers. As described in additional detail below, the present invention involves disposing clog-preventing structures similar to those described above into these dead volume spaces in order to facilitate reliable co-extrusion processing.

Referring to FIG. 8, material feed system 60E represents exemplary experimental arrangement utilized to produce solar cells on a small scale, and those skilled in the art will recognize that other arrangements would typically be used to produce solar cells on a larger scale. Referring to the upper portion of FIG. 8, material feed system 60E includes a pair of housings 62-1 and 62-2 that respectively support pneumatic cylinders 64-1 and 64-2, which is operably coupled to cartridges 66-1 and 66-2 such that material forced from these cartridges respectively passes through feedpipes 68-1 and 68-2 into printhead assembly 100E. As indicated in the lower portion of FIG. 8, the Z-axis positioning mechanism (partially shown) includes a Z-axis stage 72E that is movable in the Z-axis (vertical) direction by way of a housing/actuator 74E (partially shown) using known techniques. Mounting plate 76E is rigidly connected to a lower end of Z-axis stage 72E and supports printhead assembly 100E, and a mounting frame (not shown) is rigidly connected to and extends upward from Z-axis stage 72E and supports pneumatic cylinders 64-1 and 64-2 and cartridges 66-1 and 66-2.

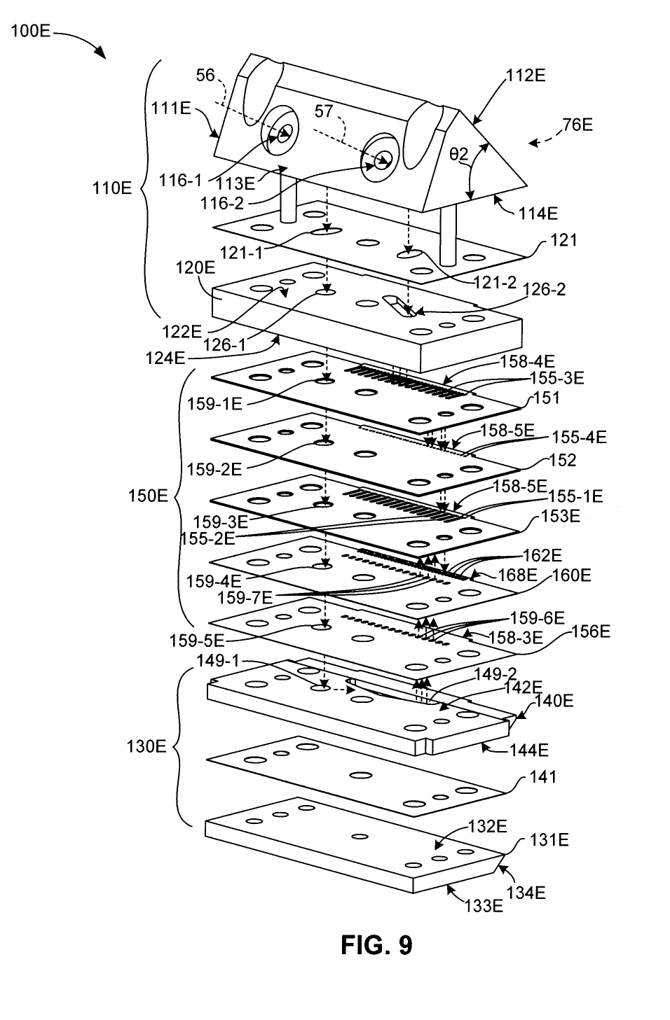

FIG. 9 is an exploded perspective view showing micro-extrusion printhead 100E in additional detail. Micro-extrusion printhead 100E includes a first (back) plate structure 110E, a second (front) plate structure 130E, and a layered nozzle structure 150E connected therebetween.

Back plate structure 110E and front plate structure 130E serve to guide the extrusion material from corresponding inlet ports 116-1 and 116-2 to layered nozzle structure 150E, and to rigidly support layered nozzle structure 150E such that extrusion nozzles 162E defined in layered nozzle structure 150E are pointed toward substrate 51 at a predetermined tilted angle (e.g., 45°), whereby extruded material traveling down each extrusion nozzle 162E toward its corresponding nozzle orifice 169E is directed toward target substrate 51.

Referring to the upper portion of FIG. 9, back plate structure 110E includes a molded or machined metal (e.g., aluminum) angled back plate 111E, a back plenum 120E, and a back gasket 121 disposed therebetween. Angled back plate 111E includes a front surface 112E, a side surface 113E, and a back surface 114E, with front surface 112E and back surface 114E forming predetermined angle θ2 (e.g., 45°). Angled back plate 111E also defines a pair of bores (not shown) that respectively extend from threaded countersunk bore inlets 116-1 and 116-2 defined in side wall 113E to corresponding bore outlets defined in back surface 114E. Back plenum 120E includes parallel front surface 122E and back surface 124E, and defines a pair of conduits (not shown) extending from corresponding inlets 126-1 and 126-2 defined through front surface 122 to corresponding outlets (not shown) defined in back surface 124E. Similar to the description provided above, the bores/conduits defined through back plate structure 110E feed extrusion material to layered nozzle structure 150E.

Referring to the lower portion of FIG. 9, front plate structure 130E includes a molded or machined metal (e.g., aluminum) front plate 131E, a front plenum 140E, and a front gasket 141 disposed therebetween. Front plate 131E includes a front surface 132E, a side surface 133E, and a beveled back surface 134E, with front surface 132E and back surface 134E forming the predetermined angle described above. Front plate 131E defines several holes for attaching to other sections of printhead assembly 100E, but does not channel extrusion material. Front plenum 140E includes parallel front surface 142E and back surface 144E, and defines a conduit (not shown) extending from corresponding inlet 148 to a corresponding outlet 149, both being defined through front surface 142E. As described below, the conduit defined in front plenum 140E serves to feed one of the extrusion materials to layered nozzle structure 150E.

Similar to the single material embodiment, described above, layered nozzle structure 150E includes a top nozzle plate 153E, a bottom nozzle plate 156E, and a nozzle outlet plate 160E sandwiched between top nozzle plate 153E and bottom nozzle plate 156E. As described in additional detail below, top nozzle plate 153E defines a row of substantially circular inlet ports (through holes) 155-1E and a corresponding series of elongated inlet ports 155-2E that are aligned adjacent to a (first) front edge 158-1E. Bottom nozzle plate 156E is a substantially solid (i.e., continuous) plate having a (third) front edge 158-2E, and defines several through holes 159-6E, whose purpose is described below. Nozzle outlet plate 160E includes a (second) front edge 168E, and defines a row of three-part nozzle channels 162E that are described in additional detail below, and several through holes 159-7E that are aligned with through holes 159-6E. When operably assembled, nozzle outlet plate 160E is sandwiched between top nozzle plate 153E and bottom nozzle plate 156E to form a series of nozzles in which each three-part nozzle channel 162E is enclosed by corresponding portions of top nozzle plate 153E and bottom nozzle plate 156E in the manner described above, with each part of three-part nozzle channel 162E aligned to receive material from two inlet ports 155-1E and one elongated inlet port 155-2E. As described in additional detail below, this arrangement produces parallel high-aspect ratio gridline structures (beads) in which a gridline material is pressed between two sacrificial material sections.

In addition to top nozzle plate 153E, bottom nozzle plate 156E and nozzle outlet plate 160E, layered nozzle structure 150E also includes a first feed layer plate 151 and a second feed layer plate 152 that are stacked over top nozzle plate 153E and served to facilitate the transfer of the two extrusion materials to nozzle outlet plate 160E in the desired manner described below. First feed layer plate 151 is a substantially solid (i.e., continuous) plate having a (fourth) front edge 158-4E, and defines several Y-shaped through holes 155-3E located adjacent to front edge 158-4E, and several feed holes 159-1E whose purposes are described below. Second feed layer plate 152 is disposed immediately below first feel layer plate 151, includes a (fifth) front edge 158-5E, and defines several substantially circular through holes 155-4E located adjacent to front edge 158-5E, and several feed holes 159-2E whose purposes are described below.

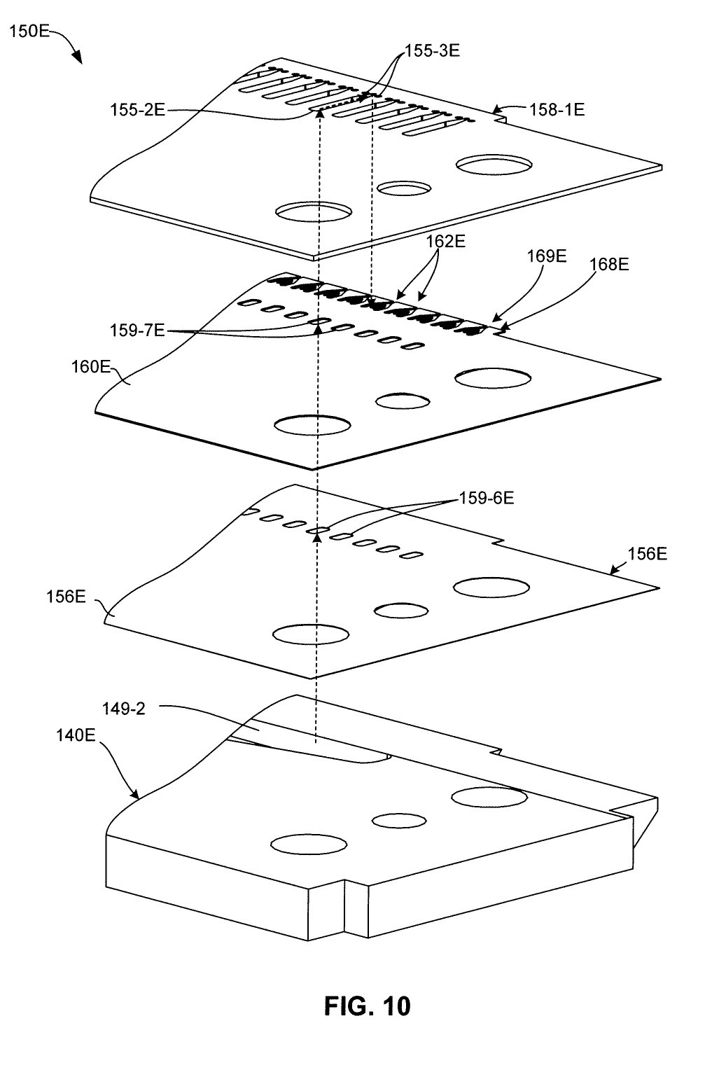

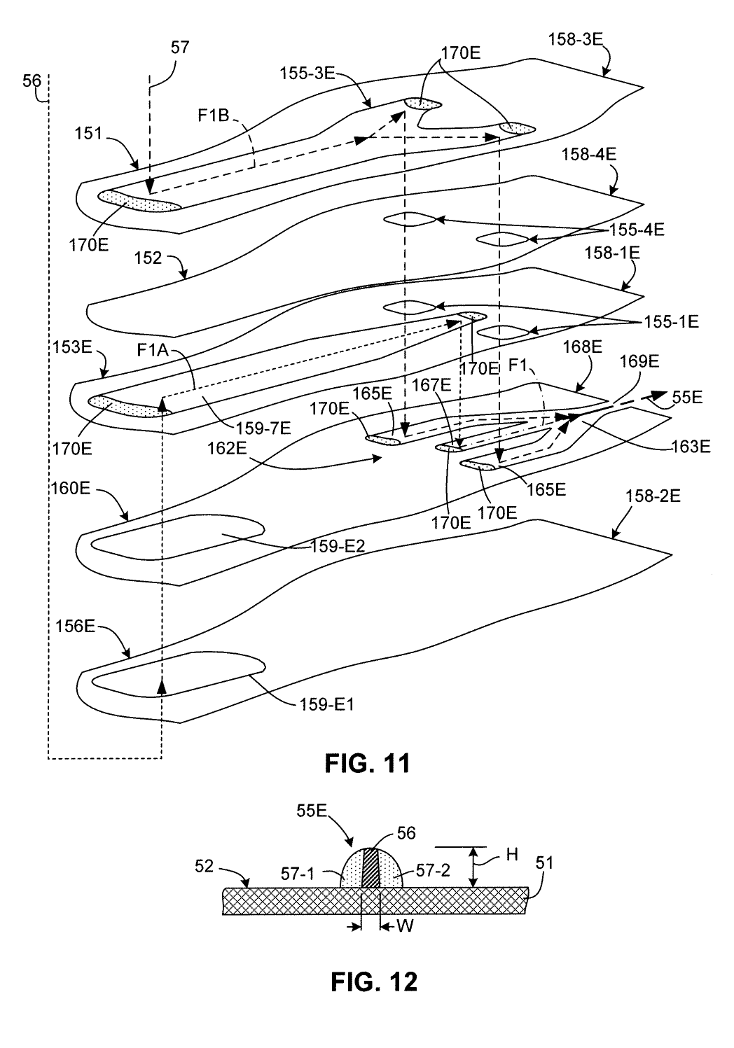

As indicated by the dashed arrows in FIG. 9 and described in additional detail in FIGS. 10 and 11, two extrusion materials are fed by way of two separate paths in a substantially Z-axis direction through the various layers of layered nozzle structure 150E to nozzle outlet plate 160E. The two flow paths are described in detail in the following paragraphs.

Referring to the upper portion of FIG. 9, gridline material 56 injected through inlet port 116-1 is fed downward through opening 121-1 in back gasket 121 and into opening 126-1 defined in back plenum 120E. The gridline material then exits back plenum 120E and passes through aligned openings 159-1E to 159-5E respectively formed in first feed layer plate 151, second feed layer plate 152, top nozzle plate 153E, nozzle outlet plate 160E, and bottom nozzle plate 156E before entering opening 149-1 of front plenum 140E. As indicated in FIG. 9 and in additional detail in FIG. 10, the gridline material is then redirected by front plenum 140E and moves upward from opening 149-2 through opening 159-6E formed in bottom nozzle plate 156E and opening 159-7E formed in nozzle outlet plate 160E. As indicated in the upper portion of FIG. 10 and in FIG. 11, the gridline material then enters the rearward end of elongated openings 159-7E, and is redirected in a substantially horizontal direction along arrow F1A to the front end of elongated opening 159-7E. The gridline material is then forced downward into a central channel 167 of three-part nozzle channel 162E. As described in additional detail below, the gridline material then flows along central channel 167E in the direction of arrow F1, and is compressed between corresponding sacrificial material portions before exiting from orifice 169E.

Referring again to the upper portion of FIG. 9, sacrificial material 57 injected through inlet port 116-2 is fed downward through opening 121-2 in back gasket 121 and into opening 126-2 defined in back plenum 120E. The sacrificial material is dispersed by plenum 120E and is passed into the rearward end of Y-shaped elongated channels 155-3E, which are formed in first feed layer plate 151. As indicated by dashed arrows in FIGS. 9 and 11, the sacrificial material flows along each Y-shaped elongated channel 155-3E to a split front end region, where the sacrificial material is distributed through corresponding openings 155-4E disposed in second feed layer plate 152 and openings 155-1E disposed in top nozzle plate 153E, and then into opposing side channel 165E of three-part nozzle channel 162E. As described in additional detail below, the sacrificial material then flows along side channels 165E, and presses against the corresponding gridline material before exiting from orifice 169E.

Referring to FIG. 11, nozzle output plate 160E includes a plate that is micro-machined (e.g., using deep reactive ion etching) to include arrowhead-shaped three-part nozzle channel 162E including a central channel 167E and opposing (first and second) side channels 165E. Central channel 167E is separated from each side channel 165E by an associated tapered finger of plate material. Central channel 167E has a closed end that is aligned to receive gridline material from the front end of elongated opening 159-7E of top nozzle plate 153E, and an open end that communicates with a merge point 166E. Similarly, side channels 165E have associated closed ends that are aligned to receive sacrificial material from corresponding openings 155-1E of top nozzle plate 153E, and open ends that communicate with a merge point 166E. Side channels 165E are angled toward central channel 167E such that sacrificial material is fed against opposing sides of the gridline material flowing in central channel 167E.

As shown in FIG. 12, the gridline material and sacrificial material co-extruded through each nozzle outlet orifice 169E (see FIG. 11) of co-extrusion printhead assembly 100E during the extrusion process forms an elongated extruded structure 55E on surface 52 of substrate 51 such that the gridline material of each structure 55E forms a high-aspect ratio gridline structure 56, and such that the sacrificial material of each structure 55E forms associated first and second sacrificial material portions 57-1 and 57-2 respectively disposed on opposing sides of the associated high-aspect ratio gridline 56. The shape of extruded structures 55E (i.e., the aspect ratio of gridline material 56 and the shape of sacrificial portions 57-1 and 57-2) are controllable through at least one of the shapes of the one or more outlet orifices and internal geometry of printhead assembly 100E, characteristics of the materials (e.g., viscosity, etc.), and the extrusion technique (e.g., flow rate, pressure, temperature, etc.). As set forth in the specific embodiment described below, the structure within the printhead assembly and the shape of the nozzle outlet orifices may be modified to further enhance the extrusion process. Suitable gridline materials 56 include, but are not limited to, silver, copper, nickel, tin, aluminum, steel, alumina, silicates, glasses, carbon black, polymers and waxes, and suitable sacrificial materials 112 include plastic, ceramic, oil, cellulose, latex, polymethylmethacrylate etc., combinations thereof, and/or variations thereof, including combining the above with other substances to obtain a desired density, viscosity, texture, color, etc. To limit the tendency for the materials to intermix after extrusion, extruded beads leaving co-extrusion printhead 100E can be quenched on substrate 51 by cooling the substrate using known techniques. Alternately, the gridline (ink) material used may be a hot-melt material, which solidifies at ambient temperatures, in which case co-extrusion printhead 100E is heated, leaving the extruded structures to solidify once they are dispensed onto substrate 51. In another technique, the materials can be cured by thermal, optical and/or other means upon exit from co-extrusion printhead 100E. For example, a curing component can be provided to thermally and/or optically cure the materials. If one or both materials include an ultraviolet curing agent, the material can be bound up into solid form in order to enable further processing without mixing.

Techniques for fabricating the various printheads described above are described, for example, in co-owned and co-pending U.S. patent application Ser. No. 11/555,512, entitled “EXTRUSION HEAD WITH PLANARIZED EDGE SURFACE”, which is incorporated herein by reference in its entirety. Alternatively, the laminated metal layer arrangements described herein, the extrusion printheads of the present invention can be manufactured by electroplating metal up through features in a patterned resist structure, by brazing together layers of etched plate metal, by generating structures out of photo-definable polymer such as SU8, or by machining or molding.

As set forth above, co-extrusion printhead 100E includes eleven layers of individually machined material that is stack bonded to form the completed printhead assembly, and dead volume spaces are unavoidable, particularly at the coupling between channels in adjacent layers. Accordingly, as shown in simplified form in FIG. 11, according to another embodiment of the present invention clog-preventing structures 170 are formed at each coupling between channels in adjacent layers.

Although the present invention has been described with respect to certain specific embodiments, it will be clear to those skilled in the art that the inventive features of the present invention are applicable to other embodiments as well, all of which are intended to fall within the scope of the present invention. For example, although described with specific reference to micro-extrusion printheads, the present invention may be utilized in other fluid conduit devices as well, such as valves.

1. A method for modifying a fluid conduit device including a body defining an inlet port, an outlet orifice, and a hollow flow channel communicating between the inlet port and the exit port, the method comprising:
causing a quantity of a first fluid to fill said flow channel, the first fluid including a hardenable material;
causing a second fluid to pass between the inlet port and the exit port through said flow channel such that a first portion of the quantity of first fluid is displaced from said flow channel by said second fluid, and such that a second portion of the quantity of first fluid remains in dead volume regions of said flow channel; and
solidifying the second portion of the quantity of first fluid remaining in said flow channel.

2. The method according to claim 1, wherein solidifying the second portion comprises causing the first fluid to solidify while said second fluid is in the flow channel.

3. The method according to claim 1, wherein solidifying the second portion comprises causing the first fluid to solidify after said second fluid is removed from the flow channel.

4. The method according to claim 1, wherein solidifying the second portion comprises inducing a chemical reaction between the first fluid and the second fluid.

5. The method according to claim 1,
wherein the first fluid comprises a thermoset material, and
wherein solidifying the second portion comprises elevating the temperature of the printhead.

6. The method according to claim 1, wherein solidifying the second portion comprises subjecting the printhead to ionizing radiation that activates a solidifying reaction in the hardenable material.

7. The method according to claim 1, wherein the first fluid and the second fluid are immiscible.

8. A fluid conduit device comprising:
a body composed substantially of a first material and defining an inlet port, an outlet orifice, and a hollow flow channel communicating between the inlet port and the exit port, wherein the flow channel includes a first flow section, a second flow section, and one of an elbow region and a neck region disposed between the first and second flow sections; and
one or more clog-preventing structures composed of a second material that is permanently attached to said first material in said at least one of said neck region and said elbow region of said flow channel.

9. The fluid conduit device of claim 8, wherein said first material comprises stainless steel and said second material comprises thermosetting plastic or thermoplastic.

10. The fluid conduit device of claim 8, wherein said body comprises a valve.

11. The fluid conduit device of claim 8, wherein said body comprises an extrusion printhead.

12. The fluid conduit device of claim 8, wherein said extrusion printhead comprises a multi-layered assembly, and said one or more one or more clog-preventing structures are disposed at couplings between adjacent ones of said layers.
